(19) United States
(12) Patent Application Publication
(10) Pub. No.: US 2014/0165389 A1
(43) Pub. Date: Jun. 19, 2014

(54) INTEGRATED CIRCUIT PACKAGING SYSTEM WITH ROUTABLE GRID ARRAY LEAD FRAME

(71) Applicants: Byung Tai DO, Singapore (SG); Arnel Senosa Trasporto, Singapore (SG); Linda Pei Ee Chua, Singapore (SG); Sung Soo Kim, Singapore (SG)

(72) Inventors: Byung Tai DO, Singapore (SG); Arnel Senosa Trasporto, Singapore (SG); Linda Pei Ee Chua, Singapore (SG); Sung Soo Kim, Singapore (SG)

(21) Appl. No.: 13/714,815

(22) Filed: Dec. 14, 2012

(51) Int. Cl. H01L 21/48

(52) U.S. Cl. CPC H01L 21/4825
USPC 29/825

(57) ABSTRACT

System and method of manufacturing an integrated circuit packaging system using routable grid array lead frame. Method includes providing a lead frame having top metal connector and bottom contact, and treating the top metal connector with an additive, or the bottom contact with an additive, or both. Concomitant to the treatment process, insulation cover or bottom encapsulation can be formed about the top metal connector or the bottom contact with respective openings. Upon coupling the interconnects to the lead frame the interconnects do not exceed the metal contacts by more than about 60% due to the treatment process.

### TECHNICAL FIELD

The present disclosure relates generally to an integrated circuit packaging system, and more particularly to system and method of manufacturing the packaging system using routable grid array lead frame.

### BACKGROUND

Increased miniaturization of components, greater packaging density of integrated circuits (“ICs”), higher performance, and lower cost are ongoing goals of the computer industry. Semiconductor packaging structures continue to advance toward miniaturization, to increase the density of the components that are packaged therein while decreasing the sizes of the products that are made therefrom. This is in response to continually increasing demands on information and communication products for ever-reduced sizes, thicknesses, and costs, along with ever-increasing performance.

These increasing requirements for miniaturization are particularly noteworthy, for example, in portable information and communication devices such as cellular phones, hands-free cellular phone headsets, personal data assistants (“FDA's”), camcorders, notebook computers, and so forth. All of these devices continue to be made smaller and thinner to improve their portability. Accordingly, IC packages that are incorporated into these devices are required to be made smaller and thinner. The packaging configurations that house and protect IC require them to be made smaller and thinner as well.

Thus, a need remains for an integrated circuit packaging system with lead frame grid-array mechanism providing low cost manufacturing, improved yields, and reduction of integrated circuit packaging dimensions, and flexible stacking and integration configurations. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### SUMMARY

Disclosed are system and method of manufacturing an integrated circuit packaging system using routable grid array lead frame. In one embodiment, a method of manufacturing an integrated circuit packaging system includes: (a) providing a lead frame having a top metal connector and a bottom cover; (b) treating the top metal connector with an additive; (c) concomitant to the treating step (b), forming an insulation cover on the lead frame having a connection opening exposing the top metal connector; and (d) connecting an internal interconnect to the top metal connector through the connection opening, wherein the internal interconnect does not exceed the top metal connector by about 60%.

In one embodiment, the providing step (a) includes the top metal connector having at least one of following compositions: Ni, Cu, Ni/Cu, Ni/Au/Cu, Ni/Pd/Cu, Ni/Pd/Au/Cu, Ni/Au/Pd/Cu, Ni/Ag/Cu and Ag/Cu. In another embodiment, the providing step (a) includes the bottom cover having at least one of following compositions: Ni, Cu, Ni/Cu, Ni/Au/Cu, Ni/Pd/Cu, Ni/Pd/Au/Cu, Ni/Au/Pd/Cu, Ni/Ag/Cu and Ag/Cu.

In one embodiment, the treating step (b) includes the additive being an organic solderability preservative.

In one embodiment, the connecting step (d) includes the internal interconnect not exceeding the connection opening by about 50%. In another embodiment, the connecting step (d) includes the internal interconnect not exceeding the connection opening by about 40%.

In one embodiment, a method of manufacturing an integrated circuit packaging system includes: (a) providing a lead frame having a top metal connector and a bottom cover; (b) treating the bottom cover with an additive; (c) concomitant to the treating steps (b), forming a bottom encapsulation on the lead frame with the bottom cover exposed from the bottom encapsulation; and (d) connecting an external interconnect to the bottom cover, wherein the external interconnect does not exceed the bottom cover by about 60%.

In one embodiment, the providing step (a) includes the top metal connector having at least one of following compositions: Ni, Cu, Ni/Cu, Ni/Au/Cu, Ni/Pd/Cu, Ni/Pd/Au/Cu, Ni/Au/Pd/Cu, Ni/Ag/Cu and Ag/Cu. In another embodiment, the providing step (a) includes the bottom cover having at least one of following compositions: Ni, Cu, Ni/Cu, Ni/Au/Cu, Ni/Pd/Cu, Ni/Pd/Au/Cu, Ni/Au/Pd/Cu, Ni/Ag/Cu and Ag/Cu.

In one embodiment, the treating step (b) includes the additive being an organic solderability preservative.

In one embodiment, the connecting step (d) includes the external interconnect not exceeding the bottom cover by about 50%. In another embodiment, the connecting step (d) includes the external interconnect not exceeding the bottom cover by about 40%.

In one embodiment, a method of manufacturing an integrated circuit packaging system includes: (a) providing a lead frame having a top metal connector and a bottom cover; (b) treating the top metal connector with a first additive and treating the bottom cover with a second additive; (c) concomitant to the treating step (b), forming an insulation cover on the lead frame having a connection opening exposing the top metal connector and forming a bottom encapsulation on the lead frame with the bottom cover exposed from the bottom encapsulation; and (d) connecting an internal interconnect to the top metal connector through the connection opening and an external interconnect to the bottom cover, wherein the internal interconnect does not exceed the top metal connector by about 60% and the external interconnect does not exceed the bottom cover by about 60%.

In one embodiment, the providing step (a) includes the top metal connector having at least one of following compositions: Ni, Cu, Ni/Cu, Ni/Au/Cu, Ni/Pd/Cu, Ni/Pd/Au/Cu, Ni/Au/Pd/Cu, Ni/Ag/Cu and Ag/Cu. In another embodiment, the providing step (a) includes the bottom cover having at least one of following compositions: Ni, Cu, Ni/Cu, Ni/Au/Cu, Ni/Pd/Cu, Ni/Pd/Au/Cu, Ni/Au/Pd/Cu, Ni/Ag/Cu and Ag/Cu.

In one embodiment, the treating step (b) includes the first additive being an organic solderability preservative. In another embodiment, the treating step (b) includes the second additive being an organic solderability preservative. In yet another embodiment, the treating step (b) includes the first additive and the second additive being the same additive.

In one embodiment, the connecting step (d) includes the internal interconnect not exceeding the connection opening by about 50% and the external interconnect not exceeding the bottom cover by about 50%. In another embodiment, the connecting step (d) includes the internal interconnect not exceeding the connection opening by about 40% and the external interconnect not exceeding the bottom cover by about 40%.

Other variations, embodiments and features of the present disclosure will become evident from the following detailed description, drawings and claims.

### BRIEF DESCRIPTION OF THE DRAWINGS

FIG. 1 is a cross-sectional view of an integrated circuit packaging system along a line 1-1 of FIG. 2 in one embodiment of the present disclosure.

FIG. 2 is a bottom view of an integrated circuit packaging system.

FIG. 3 is a flow chart of a method of manufacturing an integrated circuit packaging system according to one embodiment of the present disclosure.

FIG. 4 is a SEM cross-sectional view of a lead frame treated with an additive according to one embodiment of the present disclosure.

FIG. 5 is a SEM cross-sectional view of a lead frame without the additive treatment according to the present disclosure.

FIGS. 6-7 are top-down micrographs of a lead frame treated with an additive according to one embodiment of the present disclosure.

FIGS. 8-9 are top-down micrographs of a lead frame without the additive treatment according to the present disclosure.

### DETAILED DESCRIPTION OF THE DISCLOSURE

It will be appreciated by those of ordinary skill in the art that the embodiments disclosed herein can be embodied in other specific forms without departing from the spirit or essential character thereof. The presently disclosed embodiments are therefore considered in all respects to be illustrative and not restrictive.

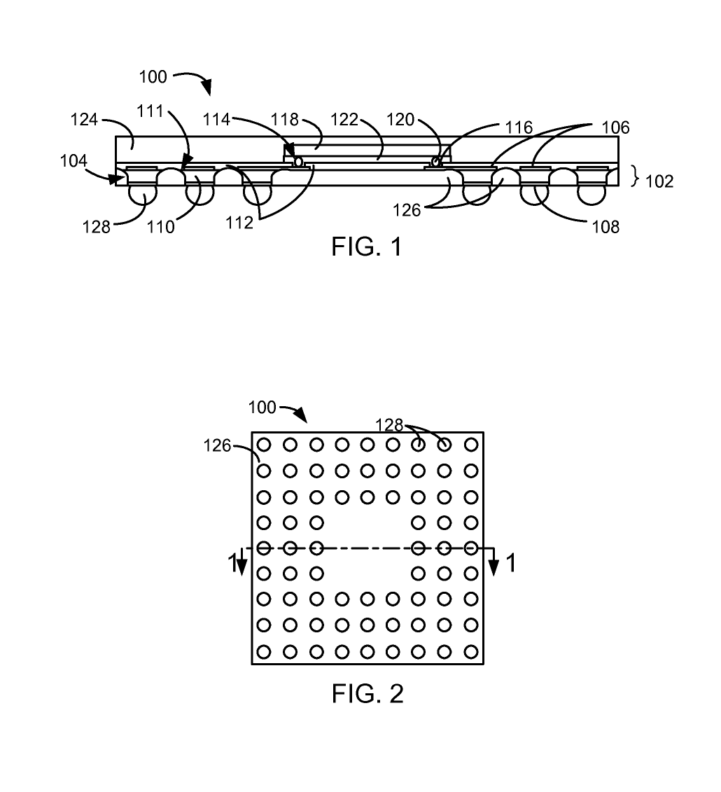

FIG. 1 is a cross-sectional view of an integrated circuit packaging system 100 along a line 1-1 of FIG. 2 in one embodiment of the present disclosure. The integrated circuit packaging system 100 includes a routing layer 102. The routing layer 102, and associated features and structures disclosed below, may also be collectively referred to as a lead frame.

The routing layer 102 can be a conductive structure used for routing electrical signals, power, ground, or reference potential for the integrated circuit packaging system 100. The routing layer 102 can route signals within the integrated circuit packaging system 100, between the integrated circuit packaging system 100 and external components or structures, or a combination thereof. The routing layer 102 can have a conductive land 104 and a metal connector 106.

The conductive land 104 can be a conductive portion within the routing layer 102 for routing electrical signals, power, ground or any reference potential in a non-horizontal direction. The conductive land 104 can be located on a lower portion of the integrated circuit packaging system 100. The conductive land 104 can extend in a non-horizontal direction. The conductive land 104 can have a bottom cover 108 and a column portion 110.

The bottom cover 108 can be an electrically conductive material for interfacing with components or structures external to the integrated circuit packaging system 100. The bottom cover 108 can be directly on a bottom portion of the column portion 110. The bottom cover 108 can also be used to shape and form the conductive land 104. The manufacturing process of the integrated circuit packaging system 100, including shaping and forming of the conductive land 104, may be similar to those disclosed in US Patent Application No. 2012/0280390, filed May 5, 2011 and published Nov. 8, 2012, which is incorporated herein by reference.

In one embodiment, the bottom cover 108 can be a nickel material. In another embodiment, the bottom cover 108 can be of a copper material. In some embodiments, the bottom cover 108 can have at least one of the following compositions: Ni/Cu, Ni/Au/Cu, Ni/Pd/Cu, Ni/Pd/Au/Cu, Ni/Au/Pd/Cu, Ni/Ag/Cu and Ag/Cu. In other embodiments, the bottom cover 108 can be formed of other suitable metallic materials and/or compositions. The bottom cover 108 may be formed by electroplating, physical vapor deposition, chemical vapor deposition, or other suitable deposition techniques.

The column portion 110 can be made from any number of materials. For example, the column portion 110 can be made from metal, such as copper or aluminum, or an alloy. The column portion 110 can be electrically conductive. The column portion 110 can have a non-horizontal wall connected to a top surface of the column portion 110 or an overhang portion 111 located at a top portion of the column portion 110. The non-horizontal wall and the overhang portion 111 of the column portion 110 can be joined to form an angle or a concave curve and to provide mold-locking features.

For example, the overhang portion 111 can have the top surface of the column portion 110 extending past the non-horizontal wall of the column portion. The top surface and the bottom surface of the overhang portion 111 can join and form an acute or a right angle. The bottom surface of the overhang portion 111 can extend to and be integral with the non-horizontal wall. The bottom surface of the overhang portion 111 can form an obtuse or a right angle with the non-horizontal wall. The bottom surface of the overhang portion 111 can also form a concaved curved surface with the non-horizontal wall.

The metal connector 106 can be directly on a top portion of the conductive land 104. The metal connector 106 can be conductive and extend horizontally for routing electrical signals along a horizontal plane. For example, the metal connector 106 can connect the conductive land 104, another component or structure within the integrated circuit packaging system 100, or a combination thereof. In some embodiments, the metal connector 106 can be a trace, a wire, a pad, a connector, or a combination thereof.

Like the bottom cover 108, in one embodiment, the top metal connector 106 can be a nickel material. In another embodiment, the top metal connector 106 can be of a copper material. In some embodiments, the top metal connector 106 can have at least one of the following compositions: Ni/Cu, Ni/Au/Cu, Ni/Pd/Cu, Ni/Pd/Au/Cu, Ni/Au/Pd/Cu, Ni/Ag/Cu and Ag/Cu. In other embodiments, the top metal connector 106 can be formed of other suitable metallic materials and/or compositions. The top metal connector 106 may be formed by electroplating, physical vapor deposition, chemical vapor deposition, or other suitable deposition techniques.

The integrated circuit packaging system 100 can have an insulation cover 112. The insulation cover 112 can be a non-conductive material for covering the routing layer 102. For example, the insulation cover 112 can be ceramic, solder resist, dielectric structure, or a combination thereof. The insulation cover 112 can be directly on the routing layer 102. The insulation cover 112 can selectively expose only portions of the routing layer 102 necessary for electrically connecting to other components or structures.

The insulation cover 112 can be directly on a top or side portion of the metal connector 106, a top or side portion of the conductive land 104, or a combination thereof. The insulation cover 112 can extend horizontally and over the metal connector 106, the conductive land 104, or a combination thereof. The insulation cover 112 can cover the top portion of the metal connector 106, the top portion of the conductive land 104, or a combination thereof.

The insulation cover 112 can have a connection opening 114 for selectively connecting components or structures to the metal connector 106, the conductive land 104, or a combination thereof. The connection opening 114 of the insulation cover 112 can expose the metal connector 106, the conductive land 104, or a combination thereof from the insulation cover 112. The insulation cover 112 can partially or completely cover the top portion of the metal connector 106, the top portion of the conductive land 104, or a combination thereof.

The routing layer 102 can have a connection enhancer 116, such as a solder wettable material, in the connection opening 114. The connection enhancer 116 can be on the top portion of the metal connector 106, the top portion of the conductive land 104, or a combination thereof. The connection enhancer 116 can be only on the portions of the metal connector 106, the conductive land 104, or a combination thereof exposed by the connection opening 114.

The integrated circuit packaging system 100 can have an integrated circuit die 118, such as a wire bond die or a flip chip, connected to the metal connector 106 through an internal interconnect 120, such as a bond wire or a solder bump. The integrated circuit die 118 can be attached on the insulation cover 112 and can be over the insulation cover 112, the metal connector 106, the conductive land 104, or a combination thereof. The internal interconnect 120 can be in the connection opening 114 and directly on the integrated circuit die 118, the metal connector 106, the conductive land 104, or a combination thereof.

In one embodiment, before the internal interconnect 120 can be coupled to the top metal connector 106, the top metal connector 106 may be treated with an additive. The treatment can be carried out by coating, chemical vapor deposition or physical vapor deposition, or other suitable coating or deposition techniques. In one embodiment, the additive can be an organic solderability preservative (OSP). In some embodiments, the additive can be a copper OSP (CuOSP) or other suitable organic coating or material.

In operation, the additive can better prevent or control the spread of solder bump, when solder bump is used as the internal interconnect 120. The internal interconnect 120, coupled to the top metal connector 106 treated with the additive, may also exhibit better structural distribution compared to an internal interconnect 120 coupled to the top metal connector 106 without any additive treatment. This will be better shown in subsequent figures and discussion.

It will be appreciated by one skilled in the art that, in one embodiment, the insulation cover 112 and the connection opening 114 may be formed on the top metal connector 106 prior to the treatment of the additive. In the alternative, the top metal connector 106 may be treated with the additive prior to the formation of the insulation cover 112 and the connection opening 114 by known processing steps. In other words, the top metal connector 106 may be treated with the additive before or after formation of the insulation cover 112 and formation of the connection opening 114. The treatment of the additive, however, need to take place prior to coupling the internal interconnect 120 and the top metal connector 106.

The integrated circuit packaging system 100 can have an under-fill 122, such as a capillary or a mold type. The under-fill 122 can be between, directly on, or a combination thereof for the integrated circuit die 118, the internal interconnect 120, the insulation cover 112, the metal connector 106, the conductive land 104, or a combination thereof. The under-fill 122 can also be in the connection opening 114.

The integrated circuit packaging system 100 can have a top encapsulation 124, a bottom encapsulation 126, and an external interconnect 128. The top encapsulation 124 can be over, encapsulate, be directly on, or a combination thereof for the integrated circuit die 118, the internal interconnect 120, the under-fill 122, the insulation cover 112, or a combination thereof. The bottom encapsulation 126 can be under the integrated circuit die 118.

The bottom encapsulation 126 can encapsulate and be directly on the conductive land 104 and can be between multiple instances of the conductive land 104. A bottom surface of the bottom encapsulation 126 can be coplanar with a bottom surface of the conductive land 104. The bottom surface of the bottom encapsulation 126 can also be lower than the bottom surface of the conductive land 104 and have the conductive land 104, the bottom cover 108, or a combination thereof in an indentation of the bottom encapsulation 126.

The top encapsulation 124 and the bottom encapsulation 126 can be formed separately at different times during the manufacturing process. The insulation cover 112, the metal connector 106, the conductive land 104, or a combination thereof can form a continuous horizontal plane between the top encapsulation 124 and the bottom encapsulation 126, and isolate the two-encapsulation structures.

In one embodiment, as the bottom encapsulation 126 is formed exposing the bottom cover 108, the bottom cover 108 may be treated with an additive. The treatment can be carried out by coating, chemical vapor deposition or physical vapor deposition, or other suitable coating or deposition techniques. In one embodiment, the additive can be an organic solderability preservative (OSP). In some embodiments, the additive can be a copper OSP (CuOSP) or other suitable organic coating or material.

In operation, the additive can better prevent or control the spread of solder bump, when solder bump is used as the external interconnect 128. The external interconnect 128, coupled to the bottom cover 108 treated with the additive, may also exhibit better structural distribution compared to an external interconnect 128 coupled to the bottom cover 108 without any additive treatment. This will be better shown in subsequent figures and discussion.

It will be appreciated by one skilled in the art that, in one embodiment, the bottom encapsulation 126 may be formed on the conductive land 104 exposing the bottom cover 108 prior to the treatment of the additive. In the alternative, the bottom cover 108 may be treated with the additive prior to formation of the bottom encapsulation 126 by known processing steps. In other words, the bottom cover 108 may be treated with the additive before or after formation of the bottom encapsulation 126. The treatment of the additive, however, need to take place prior to coupling of the bottom cover 108 with the external interconnect 128.

The integrated circuit packaging system 100 can have the routing layer 102 formed from a lead frame and not a substrate structure. For example, the integrated circuit packaging system 100 can be without an inner support portion, such as such as a pre-impregnated layer in substrates, or have the routing layer 102 directly on both the insulation cover 112 and the bottom encapsulation 126.

In some embodiments, a lead frame can have a support portion (not shown) for minimizing bowing damage during manufacturing and provide improved yield. The support portion may be an area underneath the internal interconnect 120 adjacent the under-fill 122 where the conductive land 104 may not be completely removed (e.g., etched) during the formation of the bottom cover 108. In some instances, the support portion may be in open or unpopulated areas and employ dummy pads to minimize or prevent bowing of the lead frame. In other instances, organic and/or inorganic materials may be applied to protect areas of the conductive land 104 during the etching or removal process as necessary.

The external interconnect 128 can be a conductive structure for electrically coupling the integrated circuit packaging system 100 to other structures, such as components or other packages. For example, the external interconnect 128 can be a solder ball, conductive posts, lands, or a combination thereof. The external interconnect 128 can be directly on the bottom portion of the conductive land 104.

In some embodiments, the insulation cover 112 can be directly on the routing layer 102 having the conductive land 104 without any inner support portions, such as the pre-impregnated layer in substrates, to provide increased versatility while improving yield and manufacturing cost. The insulation cover 112 directly on the routing layer 102 having the conductive land 104 without any inner support portions enables using lead frames having signal routing mechanisms to manufacture lead frame grid-array types of packages. The insulation cover 112 further provides protection against shorts and damages to the conductive portions.

In other embodiments the, the insulation cover 112 having the connection opening 114 over the routing layer 102 formed from the lead frame and not the substrate structure can provide improved yield and lower manufacturing cost. The insulation cover 112 having the connection opening 114 reduces the manufacturing complexity and material necessary to provide protection against shorts and damages to the conductive portions for lead frames. In some instances, the insulation cover 112 having the connection opening 114 only directly under the internal interconnect 120 can provide protection of the routing layer 102 while maintaining lower manufacturing cost.

In one embodiment, the conductive land 104 having the overhang portion 111 on the top portion thereof can provide improved mold lock capability for the routing layer 102 while maintaining lower manufacturing cost. The overhang portion 111 on the top portion of the conductive land 104 can be a characteristic of shaping the conductive land 104 from the bottom side only instead of from both top and the bottom. The single direction of shaping eliminates the need to separately design the shaping process from an addition direction.

FIG. 2 is a bottom view of the integrated circuit packaging system 100. The integrated circuit packaging system 100 can have the conductive land 104 of FIG. 1 and the external interconnect 128 arranged in along a straight line. The integrated circuit packaging system 100 can also have the conductive land 104 and the external interconnect 128 arranged in a shape of an oval or a rectangle, or in multiple concentric ovals or rectangles. The arrangement of the conductive land 104 and the external interconnect 128 can also be customized for the integrated circuit packaging system 100.

In one embodiment, the conductive land 104, the metal connector 106 of FIG. 1, and the insulation cover 112 of FIG. 1 can allow for increased design versatility while improving yield and manufacturing cost. The conductive land 104 and the metal connector 106 can be arranged to physically route the signals, while the insulation cover 112 can provide protection and stability to the conductive land 104 and the metal connector 106 within the integrated circuit packaging system 100.

The integrated circuit packaging system 100 can also have the bottom portion of the conductive land 104 exposed between the bottom encapsulation 126 and the external interconnect 128. The external interconnect 128, the bottom encapsulation 126, or a combination thereof can also fully cover the bottom portion of the conductive land 104.

In one embodiment, the integrated circuit packaging system 100 is a current routable lead frame grid-array structure having a flip chip integrated circuit die 118, with the top encapsulation 124 protecting the flip chip integrated circuit die 118.

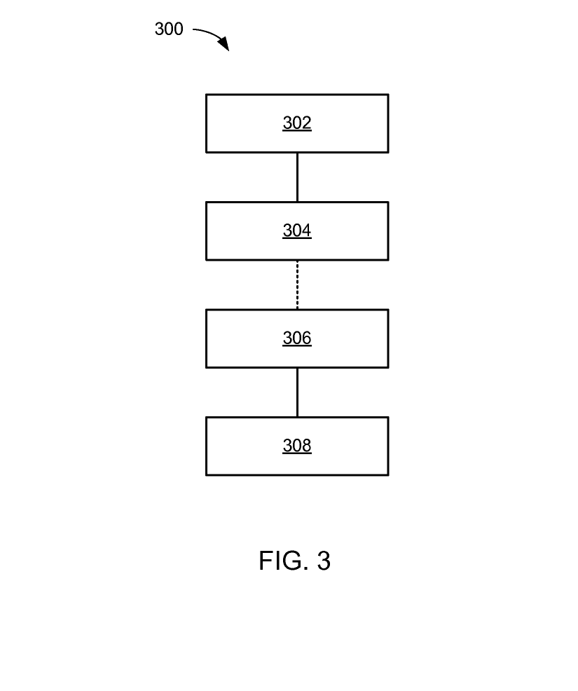

FIG. 3 is a flow chart of a method 300 of manufacturing an integrated circuit packaging system 100 according to one embodiment of the present disclosure. Specifically, an objective of the method 300 is to control solder flow for a routable lead frame grid array using an additive surface treatment process.

In one embodiment, the method 300 includes: step (a) 302 of providing a lead frame having a top metal connector and a bottom cover; step (b) 304 of treating the top metal connector with an additive; step (c) 306 of concomitant to the treating step (b) 304, forming an insulation cover on the lead frame having a connection opening exposing the top metal connector; and step (d) 308 of connecting an internal interconnect to the top metal connector through the connection opening, whereby the internal interconnect does not exceed the top metal connector by about 60%.

It will be appreciated by one skilled in the art that the processing steps (b) 304 and (c) 306 may be interchangeable. In other words, the insulation cover and the connection opening may be formed on the top metal connector prior to the additive treatment, or thereafter as described above. Furthermore, it will be understood that these processing steps (b) 304 and (c) 306 may be carried out via known processing steps and techniques including without limitation, wet chemical coating, and lithographic exposure and developing of patterns, deposition of dielectric or metallic materials, and etching or removal of photoresist, dielectric and metal.

In one embodiment, the additive can be an organic solderability preservative (OSP). In some embodiments, the additive can be a copper OSP or other suitable organic coating or material.

In some embodiments, the top metal connector and the bottom cover can have at least one of the following compositions: Ni, Cu, Ni/Cu, Ni/Au/Cu, Ni/Pd/Cu, Ni/Pd/Au/Cu, Ni/Au/Pd/Cu, Ni/Ag/Cu and Ag/Cu. Although not greater than about 60% is disclosed, in some instances the internal interconnect does not exceed the top metal connector by about 50%, or by about 40%.

In one embodiment, the method 300 includes: step (a) 302 of providing a lead frame having a top metal connector and a bottom cover; step (b) 304 of treating the bottom cover with an additive; step (c) 306 of concomitant to the treating step (b) 304, forming a bottom encapsulation on the lead frame with the bottom cover exposed from the bottom encapsulation; and step (d) 308 of connecting an external interconnect to the bottom cover, whereby the external interconnect does not exceed the bottom cover by about 60%.

Similar to above, it will be appreciated by one skilled in the art that the processing steps (b) 304 and (c) 306 may be interchangeable. In other words, the bottom cover may be exposed from the bottom encapsulation prior to the additive treatment, or thereafter as described above. Furthermore, it will be understood that these processing steps (b) 304 and (c) 306 may be carried out via known processing steps and techniques including without limitation, wet chemical coating, and lithographic exposure and developing of patterns, deposition of dielectric or metallic materials, and etching or removal of photoresist, dielectric and metal.

Further, in some embodiments, the additive can be a copper organic solderability preservative (OSP) or other suitable organic coating or material.

In some embodiments, the top metal connector and the bottom cover can have at least one of the following compositions: Ni, Cu, Ni/Cu, Ni/Au/Cu, Ni/Pd/Cu, Ni/Pd/Au/Cu, Ni/Au/Pd/Cu, Ni/Ag/Cu and Ag/Cu. Although not greater than about 60% is disclosed, in some instances the external interconnect does not exceed the bottom cover by about 50%, or by about 40%.

In one embodiment, the method 300 includes: step (a) 302 of providing a lead frame having a top metal connector and a bottom cover; step (b) 304 of treating the top metal connector with a first additive and treating the bottom cover with a second additive; step (c) 306 of concomitant to the treating step (b) 304, forming an insulation cover on the lead frame having a connection opening exposing the top metal connector and forming a bottom encapsulation on the lead frame with the bottom cover exposed from the bottom encapsulation; and step (d) 308 of connecting an internal interconnect to the top metal connector through the connection opening and an external interconnect to the bottom cover, whereby the internal interconnect does not exceed the top metal connector by about 60% and the external interconnect does not exceed the bottom cover by about 60%.

Similar to above, it will be appreciated by one skilled in the art that the processing steps (b) 304 and (c) 306 may be interchangeable. In other words, the insulation cover and the connection opening may be formed on the top metal connector prior to the additive treatment, or thereafter as described above. Likewise, the bottom cover may be exposed from the bottom encapsulation prior to the additive treatment, or thereafter as described above. Although two additives are described, the first additive and the second additive may be the same additive and the treating step (b) 304 of the top metal connector and the bottom cover can be carried out at the same time. Furthermore, it will be understood that these processing steps (b) 304 and (c) 306 may be carried out via known processing steps and techniques including without limitation, wet chemical coating, and lithographic exposure and developing of patterns, deposition of dielectric or metallic materials, and etching or removal of photoresist, dielectric and metal.

Further, in one embodiment, the first additive can be a copper organic solderability preservative (OSP) while the second additive can be other suitable organic coating or material. In another embodiment, the first additive can be a suitable organic coating or material while the second additive can be a Cu OSP. In the alternative, the two additives may be the same.

In some embodiments, the top metal connector and the bottom cover can have at least one of the following compositions: Ni, Cu, Ni/Cu, Ni/Au/Cu, Ni/Pd/Cu, Ni/Pd/Au/Cu, Ni/Au/Pd/Cu, Ni/Ag/Cu and Ag/Cu. Although not greater than about 60% is disclosed, in some instances the internal interconnect does not exceed the top metal connector by about 50%, or by about 40%, and the external interconnect does not exceed the bottom cover by about 50%, or by about 40%.

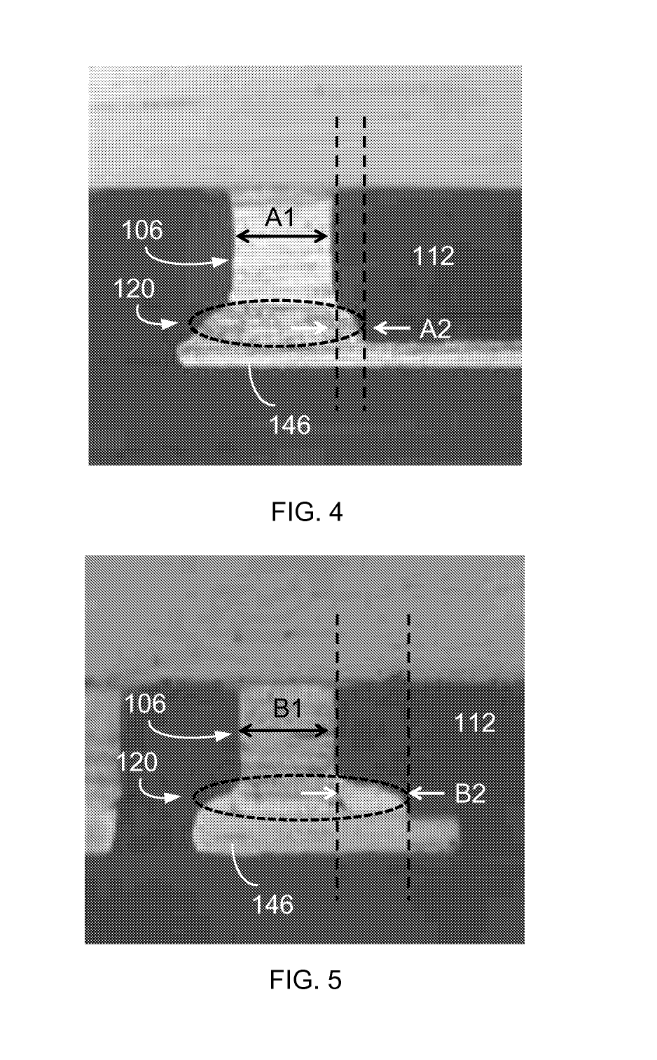

FIG. 4 is a SEM cross-sectional view of a lead frame treated with an additive according to one embodiment of the present disclosure. In this example, the surface finish of the top metal connector 106 has been treated with Cu OSP. The internal interconnect 120 is connected to the top metal connector 106 through the connection opening, the structures being surrounded by the insulation cover 112, which in this case is solder resist. The internal interconnect 120, with a Sn_{2.5}Ag solder composition, is not only more compact and controlled as illustrated by the dashed oval outline, but the solder spread out has a ratio of about 34% (Ratio=A2/A1=22 microns/65 microns). Due to the more controlled solder spread out, additional interconnect 146 such as copper metal trace may be formed for additional packaging functionalities.

FIG. 5 is a SEM cross-sectional view of a lead frame without the additive treatment according to the present disclosure. In this example, the surface finish of the top metal connector 106 has been subjected to electroless nickel-electroless palladium-immersion gold (ENEPIG) process. The internal interconnect 120 is connected to the top metal connector 106 through the connection opening, the structures being surrounded by the insulation cover 112, which in this case is solder resist. The internal interconnect 120, with a Sn_{2.5}Ag solder composition, exhibits more distortion and spread out as illustrated by the dashed oval outline, with the solder spread out having a ratio of about 68% (Ratio=B2/B1=44 microns/65 microns). Like above, additional interconnect 146 such as copper metal trace may be formed for additional packaging functionalities.

Accordingly, the internal interconnect 120 coupled or connected to the top metal connector 106 through the connection opening, when the top metal connector 106 has been treated with an additive according to one embodiment of the present disclosure, allows the internal interconnect 120 to not exceed the top metal connector 106 by about 60%. In some embodiments, the internal interconnect 120 does not exceed the top metal connector 106 by about 50%, or by about 40%, or by about 30%, or by about 20%, or by about 10%.

It will be appreciated by one skilled in the art that although no SEM cross-sections of the external interconnect 128 and the bottom cover 108 are shown, similar trends and behavior may be demonstrated, where the external interconnect 128 does not exceed the bottom cover 108 by about 60%, or by about 50%, or by about 40%, or by about 30%, or by about 20%, or by about 10%.

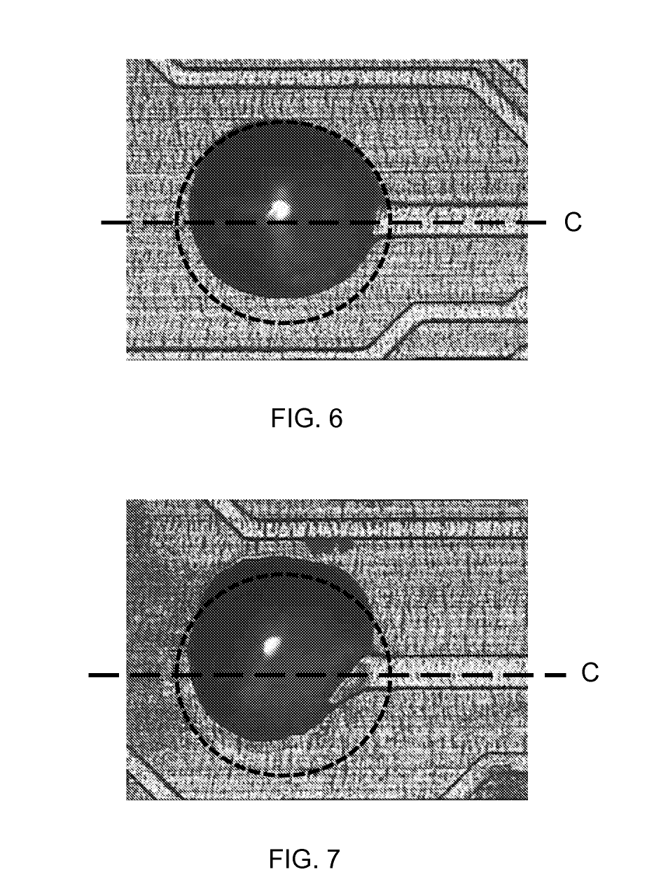

FIGS. 6-7 are top-down micrographs of a lead frame treated with an additive according to one embodiment of the present disclosure. In this instance, the surface has been treated with Cu OSP prior to formation of the solder bumps and reflowing of the same. At 100× magnification, there is less spread out from the center of the solder ball and more uniformity in shape due to treatment of the top metal surface with an additive according to one embodiment of the present disclosure. In other words, the solder ball is formed substantially about the center of the metal line C and being substantially spherical in shape as outlined by the dashed circle.

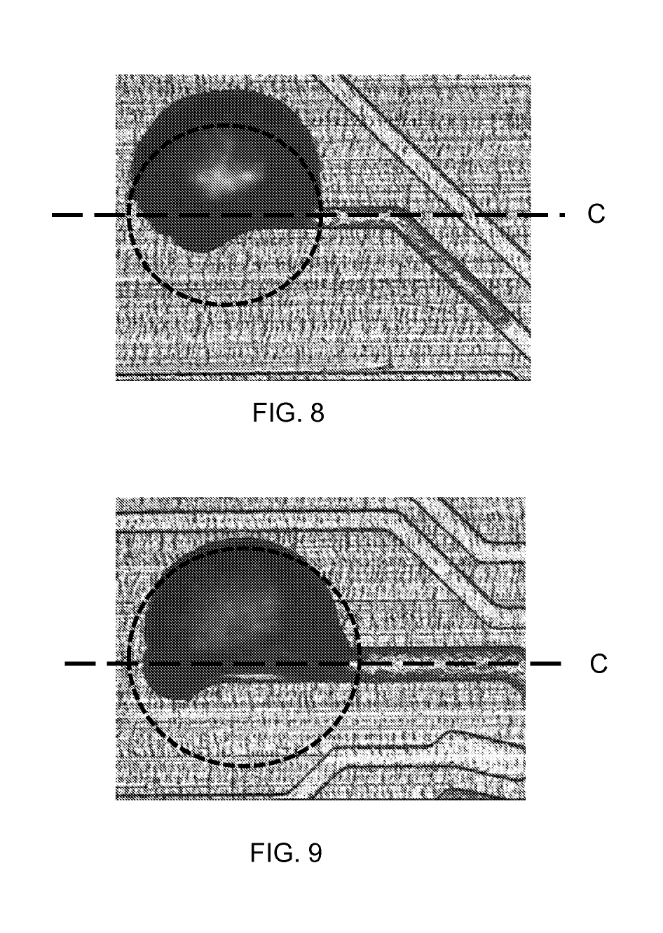

FIGS. 8-9 are top-down micrographs of a lead frame without the additive treatment according to the present disclosure. In this instance, the top trace surface is formed of a Ni/Pd/Au material without any additive treatment, with the solder bump formed thereon and reflowed. At 100× magnification, there is considerably more spread out from the center of the solder ball and more distorted shape due to the lack of treatment with an additive. In other words, the solder ball is formed substantially off-center of the metal line C, almost to one side of the line, with the shape of the solder ball being substantially distorted from a standard spherical shape.

Although the current description has been described in detail with reference to several embodiments, additional variations and modifications exist within the scope and spirit of the disclosure.

What is claimed is:

1. A method comprising:
(a) providing a lead frame having a top metal connector and a bottom cover;
(b) treating the top metal connector with an additive;
(c) concomitant to the treating step (b), forming an insulation cover on the lead frame having a connection opening exposing the top metal connector; and
(d) connecting an internal interconnect to the top metal connector through the connection opening, wherein the internal interconnect does not exceed the top metal connector by about 60%.

2. The method of claim 1, wherein the providing step (a) includes the top metal connector having at least one of following compositions: Ni, Cu, Ni/Cu, Ni/Au/Cu, Ni/Pd/Cu, Ni/Pd/Au/Cu, Ni/Au/Pd/Cu, Ni/Ag/Cu and Ag/Cu.

3. The method of claim 1, wherein the providing step (a) includes the bottom cover having at least one of following compositions: Ni, Cu, Ni/Cu, Ni/Au/Cu, Ni/Pd/Cu, Ni/Pd/Au/Cu, Ni/Au/Pd/Cu, Ni/Ag/Cu and Ag/Cu.

4. The method of claim 1, wherein the treating step (b) includes the additive being an organic solderability preservative.

5. The method of claim 1, wherein the connecting step (d) includes the internal interconnect not exceeding the connection opening by about 50%.

6. The method of claim 1, wherein the connecting step (d) includes the internal interconnect not exceeding the connection opening by about 40%.

7. A method comprising:
(a) providing a lead frame having a top metal connector and a bottom cover;
(b) treating the bottom cover with an additive;
(c) concomitant to the treating steps (b), forming a bottom encapsulation on the lead frame with the bottom cover exposed from the bottom encapsulation; and
(d) connecting an external interconnect to the bottom cover, wherein the external interconnect does not exceed the bottom cover by about 60%.

8. The method of claim 7, wherein the providing step (a) includes the top metal connector having at least one of following compositions: Ni, Cu, Ni/Cu, Ni/Au/Cu, Ni/Pd/Cu, Ni/Pd/Au/Cu, Ni/Au/Pd/Cu, Ni/Ag/Cu and Ag/Cu.

9. The method of claim 7, wherein the providing step (a) includes the bottom cover having at least one of following compositions: Ni, Cu, Ni/Cu, Ni/Au/Cu, Ni/Pd/Cu, Ni/Pd/Au/Cu, Ni/Au/Pd/Cu, Ni/Ag/Cu and Ag/Cu.

10. The method of claim 7, wherein the treating step (b) includes the additive being an organic solderability preservative.

11. The method of claim 7, wherein the connecting step (d) includes the external interconnect not exceeding the bottom cover by about 50%.

12. The method of claim 7, wherein the connecting step (d) includes the external interconnect not exceeding the bottom cover by about 40%.

13. A method comprising:
(a) providing a lead frame having a top metal connector and a bottom cover;
(b) treating the top metal connector with a first additive and treating the bottom cover with a second additive;
(c) concomitant to the treating step (b), forming an insulation cover on the lead frame having a connection opening exposing the top metal connector and forming a bottom encapsulation on the lead frame with the bottom cover exposed from the bottom encapsulation; and
(d) connecting an internal interconnect to the top metal connector through the connection opening and an external interconnect to the bottom cover, wherein the internal interconnect does not exceed the top metal connector by about 60% and the external interconnect does not exceed the bottom cover by about 60%.

14. The method of claim 13, wherein the providing step (a) includes the top metal connector having at least one of following compositions: Ni, Cu, Ni/Cu, Ni/Au/Cu, Ni/Pd/Cu, Ni/Pd/Au/Cu, Ni/Au/Pd/Cu, Ni/Ag/Cu and Ag/Cu.

15. The method of claim 13, wherein the providing step (a) includes the bottom cover having at least one of following compositions: Ni, Cu, Ni/Cu, Ni/Au/Cu, Ni/Pd/Cu, Ni/Pd/Au/Cu, Ni/Au/Pd/Cu, Ni/Ag/Cu and Ag/Cu.

16. The method of claim 13, wherein the treating step (b) includes the first additive being an organic solderability preservative.

17. The method of claim 13, wherein the treating step (b) includes the second additive being an organic solderability preservative.

18. The method of claim 13, wherein the treating step (b) includes the first additive and the second additive being the same additive.

19. The method of claim 13, wherein the connecting step (d) includes the internal interconnect not exceeding the connection opening by about 50% and the external interconnect not exceeding the bottom cover by about 50%.

20. The method of claim 13, wherein the connecting step (d) includes the internal interconnect not exceeding the connection opening by about 40% and the external interconnect not exceeding the bottom cover by about 40%.
